(19) United States
(12) Patent Application Publication
(10) Pub. No.: US 2025/0323109 A1
(43) Pub. Date: Oct. 16, 2025

(54) DISPLAY DEVICE, ELECTRONIC DEVICE INCLUDING THE SAME AND METHOD OF PROVIDING THE SAME

(71) Applicant: Samsung Display Co., Ltd., Yongin-si, Gyeonggi-do, (KR)

(72) Inventors: BYUNGHOON KANG, Yongin-si, Gyeonggi-do, (KR); SUNGHYUN KIM, Yongin-si, Gyeonggi-do, (KR); HYUNJI LEE, Yongin-si, Gyeonggi-do, (KR); MIN-HOON CHOI, Yongin-si, Gyeonggi-do, (KR)

(21) Appl. No.: 19/082,703

(22) Filed: Mar. 18, 2025

(30) Foreign Application Priority Data
Apr. 12, 2024 (KR) 10-2024-0049646

(51) Int. Cl. H01L 23/31

(52) U.S. Cl. CPC H01L 23/3121; H01L 23/3142

(57) ABSTRACT

An electronic device including a display module including a display panel, a folding region at which the display module is foldable, and a non-folding region adjacent to the folding region along a first direction, a window module on the display module and including a thin-film glass, and a coating layer which is further from the display module than the thin-film glass, and a glass substrate which faces the window module with the display module therebetween and in which a hole is defined overlapping the folding region. The coating layer has a thickness of about 50-110 micrometers together with an elastic modulus of about 500-3000 megapascals, where the coating layer having a first elastic modulus of about 500-2000 megapascals includes the first elastic modulus together with the thickness being about 80-100 micrometers.

This U.S. non-provisional patent application claims priority under 35 U.S.C. § 119 of Korean Patent Application No. 10-2024-0049646, filed on Apr. 12, 2024, the entire contents of which are hereby incorporated by reference.

### BACKGROUND

### (1) Field

The present disclosure herein relates to a display device with improved product reliability, an electronic device including the same, and a method for manufacturing (or providing) the same with a simplified process.

### (2) Description of the Related Art

A display device as an electronic device and/or as a part of an electronic device supplies a user with information by displaying various images on a display screen. In general, the display device displays the information on an assigned screen. A flexible display device including a flexible display panel is being developed. Unlike a rigid display device, the flexible display device is bendable, rollable, or flexible. The flexible display device of which a shape may be variously changed may be portable regardless of a size of the display screen, thereby improving user convenience.

### SUMMARY

The present disclosure provides a display device with excellent folding characteristics and improved product reliability.

The present disclosure also provides a method for manufacturing (or providing) a display device as an electronic device and/or as a part of an electronic device, with a simplified process.

An embodiment of the invention provides a display device as an electronic device including a display module in which a first non-folding region, a folding region, and a second non-folding region are sequentially defined along a first direction, and which includes a display panel, a window module disposed on the display module, and a lower plate which is disposed under the display module, in which at least one pattern overlapping the folding region is defined, and which is a glass substrate, where the window module includes a thin-film glass disposed on the display module, and a coating layer disposed on the thin-film glass, and having a thickness of about 50 micrometers (μm) to about 110 μm, the coating layer has an elastic modulus of about 500 megapascals (MPa) to about 3000 MPa, and the thickness is about 80 μm to about 100 μm in a first elastic modulus equal to or more than about 500 MPa and less than about 2000 MPa.

In an embodiment, the coating layer may have a thickness of about 90 μm to about 110 μm in a second elastic modulus of about 500 MPa to about 1000 MPa.

In an embodiment, the coating layer may have a thickness equal to or more than about 70 μm and less than 90 μm in a third elastic modulus more than about 1000 MPa and equal to or less than 2000 MPa.

In an embodiment, the coating layer may have a thickness of 80 μm to about 100 μm.

In an embodiment, the coating layer may be directly disposed on the thin-film glass.

In an embodiment, the window module may further include a hard coating layer disposed on the coating layer.

In an embodiment, the display module may have a torque equal to or less than about 150 N·mm.

In an embodiment, the lower plate may have a smaller thickness than the coating layer.

In an embodiment, the pattern may penetrate from a lower surface of the lower plate toward an upper surface of the lower plate.

In an embodiment, the lower plate may include a base substrate on which the pattern is defined, and at least one of a functional layer disposed on an upper surface of the base substrate, or a protective layer disposed on a lower surface of the base substrate, and the base substrate may include glass.

In an embodiment, an upper surface of the lower plate may be in direct contact with a lower surface of the display panel.

In an embodiment, the display device may further include an adhesive layer disposed between the lower plate and the display module, where the lower plate may be coupled to a lower portion of the display panel by the adhesive layer.

In an embodiment, the pattern may include a plurality of holes, the plurality of holes may extend along a second direction crossing the first direction, the plurality of holes may include first holes and second holes spaced apart from each other in the first direction, and the first holes and the second holes may be arranged misaligned.

In an embodiment of the invention, a method for manufacturing (or providing) a display device as an electronic device, the method includes forming (or providing) a lower plate which is a glass substrate, forming a display module which includes a display panel, and in which a first non-folding region, a folding region, and a second non-folding region are sequentially defined along a first direction, and forming a window module including a thin-film glass and a coating layer, where the forming of the window module includes forming the coating layer having a thickness of about 50 μm to about 110 μm by supplying a coating material on the thin-film glass, the coating layer has an elastic modulus of about 500 MPa to about 3000 MPa, and the thickness is about 80 μm to about 100 μm in a first elastic modulus equal to or more than about 500 MPa and less than about 2000 MPa.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of an unfolded state of an electronic device according to an embodiment of the invention;

FIG. 1B is a perspective view illustrating a folding operation of an electronic device according to an embodiment;

FIG. 1C is a plan view of a folded state of an electronic device according to an embodiment;

FIG. 1D is a perspective view illustrating a folding operation of an electronic device according to an embodiment;

FIG. 2 is an exploded perspective view of an electronic device according to an embodiment;

FIG. 3 is a cross-sectional view of a display device according to an embodiment of the invention;

FIG. 4 is a plan view illustrating a display device according to an embodiment;

FIG. 5 is a cross-sectional view of a display panel according to an embodiment;

FIG. 6 is a cross-sectional view illustrating a display device according to an embodiment;

FIGS. 7A to 7E are respectively cross-sectional views illustrating a display device according to embodiments;

FIGS. 8A to 8E are cross-sectional views illustrating operations of a method for manufacturing (or providing) a display device according to an embodiment;

FIGS. 9A to 9E are cross-sectional views illustrating operations of a method for manufacturing (or providing) a display device according to an embodiment; and

FIGS. 10A to 10E are cross-sectional views illustrating operations of a method for manufacturing (or providing) a display device according to an embodiment.

FIG. 11 is a block diagram illustrating an electronic device according to an embodiment.

### DETAILED DESCRIPTION

In this specification, when a component (or region, layer, portion, etc.) is referred to as being related to another element such as being “on”, “connected”, or “coupled” to another component, it means that it is placed/connected/coupled directly on the other component or a third component can be disposed between them. When a component (or region, layer, portion, etc.) is referred to as being related to another element such as being “directly on”, “directly connected”, or “directly coupled” to another component, it means that no other component or third component is disposed therebetween.

The same reference numerals or symbols refer to the same elements. Within the Figures and the text of the disclosure, a reference number indicating a singular form of an element may also be used to reference a plurality of the element. In addition, in the drawings, thicknesses, ratios, and dimensions of components are exaggerated for effective description of technical content.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Hereinafter, embodiments of the invention will be described with reference to the drawings.

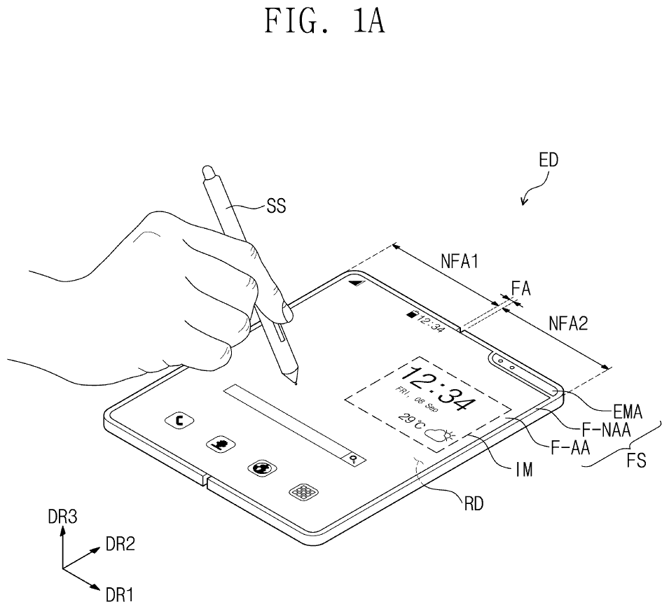

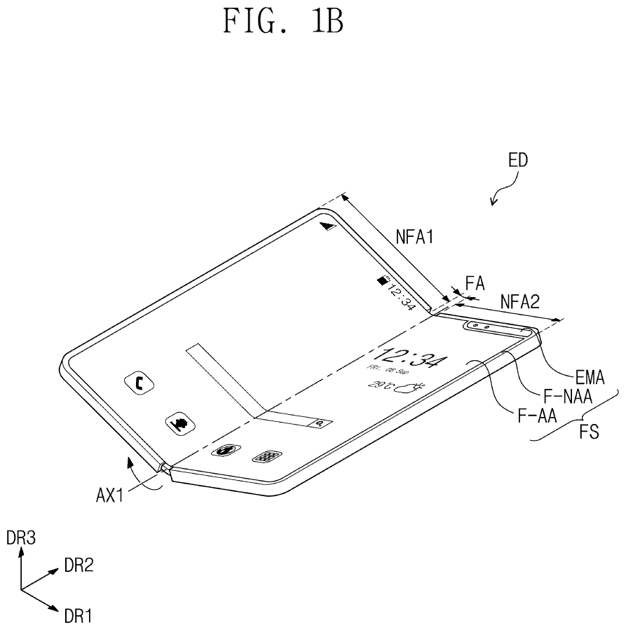

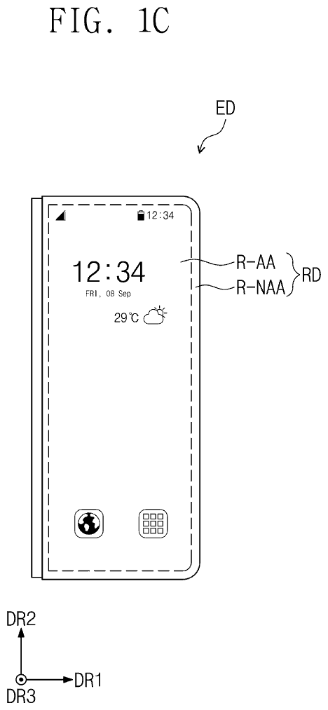

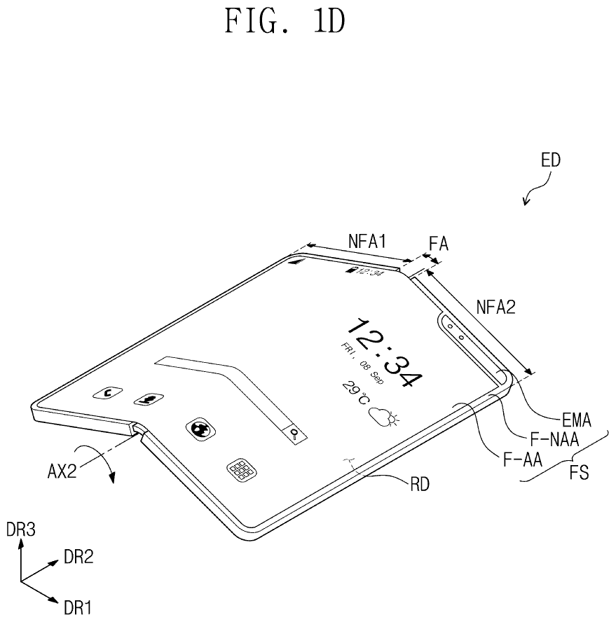

FIG. 1A is a perspective view of an unfolded state of an electronic device ED according to an embodiment of the invention. FIG. 1B is a perspective view illustrating a folding operation of the electronic device ED according to an embodiment of the invention. FIG. 1C is a plan view illustrating a folded state of the electronic device ED according to an embodiment of the invention. FIG. 1D is a perspective view illustrating a folding operation of the electronic device ED according to an embodiment of the invention.

Referring to FIG. 1A, the electronic device ED may be activated in response to an electrical signal. The electronic device ED may include various embodiments. For example, the electronic device ED may include a tablet computer, a laptop computer, a computer, a smart television, or the like. In the present embodiment, a smart phone is illustrated as an example of the electronic device ED.

The electronic device ED may include a first display surface FS defined by a surface (or plane) which is disposed in a first direction DR1 and a second direction DR2 which crosses the first direction DR1. The electronic device ED may display an image IM on the first display surface FS, toward a third direction DR3. The first display surface FS on which the image IM is displayed may correspond to a front surface of the electronic device ED. The image IM may include not only a dynamic image but also a static image. FIG. 1A illustrates an internet search window, a clock window, and a plurality of applications as an example of the image IM.

Hereinafter, a direction substantially vertically crossing (e.g., perpendicular or normal to) a plane defined by the first direction DR1 and the second direction DR2 is defined as the third direction DR3. In addition, in the present specification, the wording, “on a plane” may be defined as alone or when seen in the third direction DR3.

In addition, in the present specification, an upper surface (or front surface) and a lower surface (or rear surface) of each of the configurations are defined on the basis of a direction in which the image IM is displayed. The front surface and the rear surface may be opposed to each other in the third direction DR3, and the normal direction of each of the front surface and the rear surface may be parallel to the third direction DR3.

A distance between the front surface and the rear surface in the third direction DR3 may correspond to a thickness/height of the electronic device ED in the third direction DR3. A thickness of the electronic device ED and various components or layers thereof may be defined along the third direction DR3 (e.g., a thickness direction). Meanwhile, directions indicated by the first to third directions DR1, DR2, and DR3 are relative concepts, and may be changed to other directions.

The electronic device ED may sense an external input applied to the electronic device ED. The external input may include inputs supplied by the outside of the electronic device ED, and having various forms. For example, the external input may include not only a contact (e.g., a physical contact), but also an input applied proximate or adjacent to the electronic device ED within a predetermined distance (for example, hovering). The external input may be applied by an external object or input tool, such as a body part of a user, a stylus, a pen, etc., The external input may have various forms such as a force, pressure, temperature, and light.

FIG. 1A exemplarily illustrates the external input through a user's pen SS as the input tool. Although not shown, the pen SS may be attached to and detached from the inside or outside of the electronic device ED, and the electronic device ED may supply and receive a signal (e.g., an electronic signal) corresponding to the attachment and/or the detachment of the pen SS relative to the electronic device ED.

The electronic device ED may include the first display surface FS and a second display surface RD. Each of the first display surface FS and the second display surface RD may be a major surface of the electronic device ED. The first display surface FS may include a first active region F-AA, a first peripheral region F-NAA, and an electronic module region EMA. The second display surface RD may be defined as a surface at least partially opposing the first display surface FS, such as along the thickness direction.

The first active region F-AA may be activated in response to an electrical signal. The first active region F-AA may be a region on which the image IM is displayed, and/or at which may an input of the pen SS is sensed.

The first peripheral region F-NAA may be adjacent to the first active region F-AA. The first peripheral region F-NAA may have a predetermined color. The first peripheral region F-NAA may surround the first active region F-AA. Accordingly, a shape (e.g., a planar shape) of the first active region F-AA may be substantially defined by the first peripheral region F-NAA. However, this is illustrated as an example, and the first peripheral region F-NAA may be disposed adjacent to only one side of the first active region F-AA, or may be omitted.

Various electronic modules may be disposed in the electronic module region EMA. For example, the electronic modules may include at least any one of a camera, a speaker, an optical sensor, or a thermal sensor. The electronic module may provide a function to the electronic device ED. The electronic module region EMA may sense an external input received through the display surfaces FS and RD, or may supply a sound signal such as a voice through the display surfaces FS and RD to the outside (e.g., the outside of the electronic device ED). The electronic module as a functional component of the electronic device ED may include a plurality of configurations, and is not limited to any one embodiment. The functional component may be exposed to outside the electronic device ED to receive external input such as force, pressure, temperature, and light.

An area (e.g., a planar area) of the electronic module region EMA may be surrounded by the first peripheral region F-NAA. However, this is an example, and an embodiment of the invention is not limited thereto. For example, the electronic module region EMA may be surrounded by the first active region F-AA and the first peripheral region F-NAA, and the planar area of the electronic module region EMA may be disposed in a planar area of the first active region F-AA.

The electronic device ED according to an embodiment may include at least one folding region FA and a non-folding region provided in plural including a plurality of non-folding regions NFA1 and NFA2 extending from the folding region FA. For example, a first non-folding region NFA1, a folding region FA, and a second non-folding region NFA2 may be defined along the first direction DR1. That is, the first non-folding region NFA1 may extend from the folding region FA along an opposite direction of the first direction DR1, and the second non-folding region NFA2 may extend from the folding region FA along the first direction DR1. The folding region FA may be adjacent to the first non-folding region NFA1 and the second non-folding region NFA2, and may be folded on the basis of a folding axis AX1 or AX2 (see FIG. 1B or FIG. 1D).

Referring to FIG. 1B the electronic device ED according to an embodiment may be folded on the basis of the first folding axis AX1 extending in the second direction DR2. When the electronic device ED is folded, the folding region FA may have a predetermined curvature and a predetermined radius of curvature. The electronic device ED may be folded on the basis of the first folding axis AX1 to be deformed to an in-folded state such that the first non-folding region NFA1 and the second non-folding region NFA2 face each other, and the first display surface FS is not exposed to the outside.

FIG. 1C is a plan view of a folded state of the electronic device ED according to an embodiment of the invention.

Referring to FIG. 1C, when the electronic device ED according to an embodiment is in-folded, the second display surface RD may be exposed to outside the electronic device ED such as to be viewed by a user. In this case, the second display surface RD may include a second active region R-AA which displays an image. The second active region R-AA may be activated in response to an electrical signal. The second active region R-AA may be a region which displays an image IM, and which may sense an external input having various forms.

A second peripheral region R-NAA may be adjacent to the second active region R-AA. The second peripheral region R-NAA may have a predetermined color. The second peripheral region R-NAA may surround the second active region R-AA. In addition, although not shown, the second display surface RD may further include an electronic module region EMA in which an electronic module including various configurations is disposed, and an embodiment of the invention is not limited thereto.

FIG. 1D is a perspective view illustrating a folding operation of the electronic device ED according to an embodiment of the invention.

Referring to FIG. 1D, the electronic device ED according to an embodiment may be folded on the basis of the second folding axis AX2 extending in the second direction DR2. The electronic device ED may be folded on the basis of the second folding axis AX2 to be deformed to an out-folded state such that the first display surface FS is exposed to the outside. The second folding axis AX2 may be defined on or at the second display surface RD, while the first folding axis AX1 may be defined on or at the first display surface FS. In an embodiment, the electronic device ED may be configured to mutually repeat an in-folding or out-folding operation using a folding operation, but an embodiment of the invention is not limited thereto.

FIGS. 1A to 1D exemplarily illustrate that the electronic device ED is folded on the basis of one folding axis AX1 or AX2, but a number of a folding axis and a number of a non-folding region according thereto are not limited thereto. For example, the electronic device ED may be folded on the basis of a plurality of folding axes so that the first display surface FS and the second display surface RD may be folded to partially face each other.

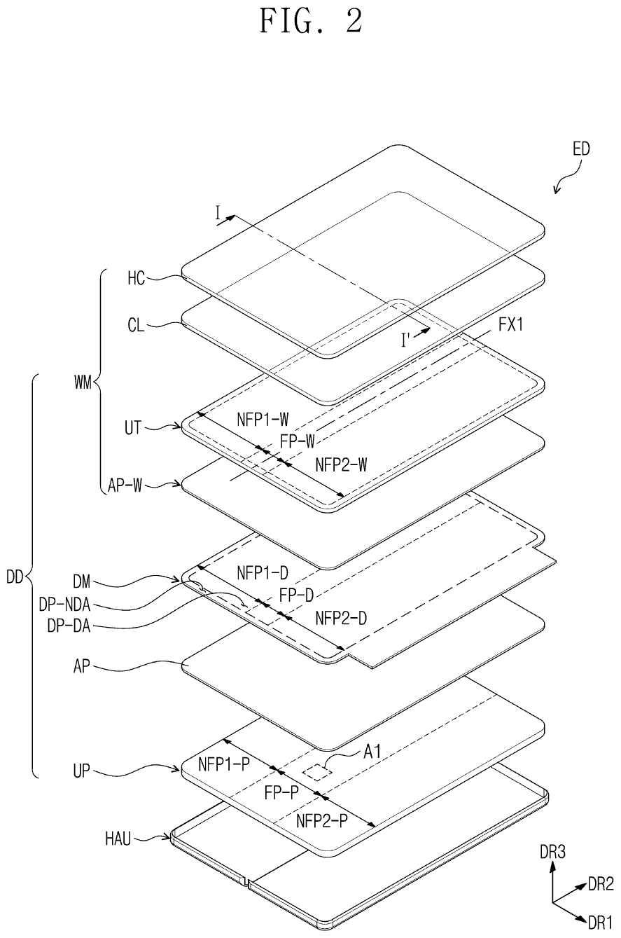

FIG. 2 is an exploded perspective view of an electronic device ED according to an embodiment. Referring to FIG. 2, the electronic device ED may include a display device DD and a housing HAU. The electronic device ED may further include an appliance structure for controlling a folding operation of the display device DD. Various components or layers of the electronic device may be foldable, rollable, bendable, etc. together with each other.

The display device DD includes a window module WM, a display module DM, and a lower plate UP. The window module WM may provide a front surface of the electronic device ED. The display module DM generates an image IM (see FIG. 1A) and senses an external input. The lower plate UP may protect the display module DM. The display device DD may further include an adhesive layer AP disposed between the display module DM and the lower plate UP.

The window module WM may include a thin-film glass UT and a coating layer CL, and may further include an outer functional layer such as a hard coating layer HC. The window module WM may include a folding portion FP-W and a non-folding portion provided in plural including non-folding portions NFP1-W and NFP2-W, respectively corresponding to each of the folding region FA (see FIG. 1A) and the non-folding regions NFA1 and NFA2 (see FIG. 1A). The first non-folding portion NFP1-W and the second non-folding portion NFP2-W may be spaced apart from each other in the first direction DR1 with the folding portion FP-W therebetween. The folding portion FP-W may be a portion of the window module WM which is foldable or bendable on the basis of the first folding axis FX1. For convenience, FIG. 2 illustrates the folding portion FP-W and the non-folding portions NFP1-W and NFP2-W only in the thin-film glass UT of the window module WM. In the present specification, the wording, “Region/portion A corresponds to region/portion B” means that A and B overlap each other on a plane or along a thickness direction, and is not limited to that A and B have the same area (e.g., same planar area).

The window module WM may include a window adhesive layer AP-W disposed between the thin-film glass UT and the display module DM. The window adhesive layer AP-W may be an optically clear adhesive (OCA) film or optically clear adhesive resin (OCR) layer. Meanwhile, in an embodiment, the window adhesive layer AP-W may be omitted.

The display module DM may include a display region DP-DA and a non-display region DP-NDA respectively corresponding to the first active region F-AA (see FIG. 1A) and the first peripheral region F-NAA (see FIG. 1A). The display region DP-DA may be defined as a region in which an image supplied by the display module DM is output.

The non-display region DP-NDA is adjacent to the display region DP-DA. For example, the non-display region DP-NDA may surround the display region DP-DA. However, this is illustrated as an example, and the non-display region DP-NDA may be defined as various shapes, and is not limited to any one embodiment.

The display module DM may include a folding display portion FP-D and a non-folding display portion provided in plural including non-folding display portions NFP1-D and NFP2-D. The folding display portion FP-D may correspond to the folding region FA1 (see FIG. 1A), and the non-folding display portions NFP1-D and NFP2-D may correspond to the non-folding regions NFA1 and NFA2 (see FIG. 1A).

The folding display portion FP-D may be folded or bent on the basis of the first folding axis FX1. The display module DM may include the first non-folding display portion NFP1-D and the second non-folding display portion NFP2-D, and the first non-folding display portion NFP1-D and the second non-folding display portion NFP2-D may be spaced apart from each other with the folding display portion FP-D therebetween.

The lower plate UP may be disposed under the display module DM. The lower plate UP may include a glass substrate. The lower plate UP may include a folding portion FP-P and a non-folding portion provided in plural including first and second non-folding portions NFP1-P and NFP2-P. The first non-folding portion NFP1-P and the second non-folding portion NFP2-P may be spaced apart from each other with the folding portion FP-P therebetween. The folding portion FP-P may correspond to the folding region FA (see FIG. 1A), and the non-folding portions NFP1-P and NFP2-P may correspond to the non-folding regions NFA1 and NFA2 (see FIG. 1A).

The adhesive layer AP may be disposed between the display module DM and the lower plate UP. The adhesive layer AP may be directly disposed on the lower plate UP. The display module DM may be directly disposed on the adhesive layer AP. However, this is an example, and an embodiment of the invention is not limited thereto. In an embodiment, the adhesive layer AP may be omitted, and the display panel DP may be directly disposed on the lower plate UP.

The adhesive layer AP may be a transparent adhesive layer including any one among a pressure sensitive adhesive (PSA) film, an optically clear adhesive (OCA) film, and an optically clear adhesive resin (OCR).

The housing HAU accommodates the display module DM and the lower plate UP. The housing HAU protects configurations, accommodated in the housing HAU, such as the display module DM and the lower plate UP. Although not shown, the electronic device ED may further include a hinge structure for easily folding or bending the housing HAU. The housing HAU may be coupled with the window module WM.

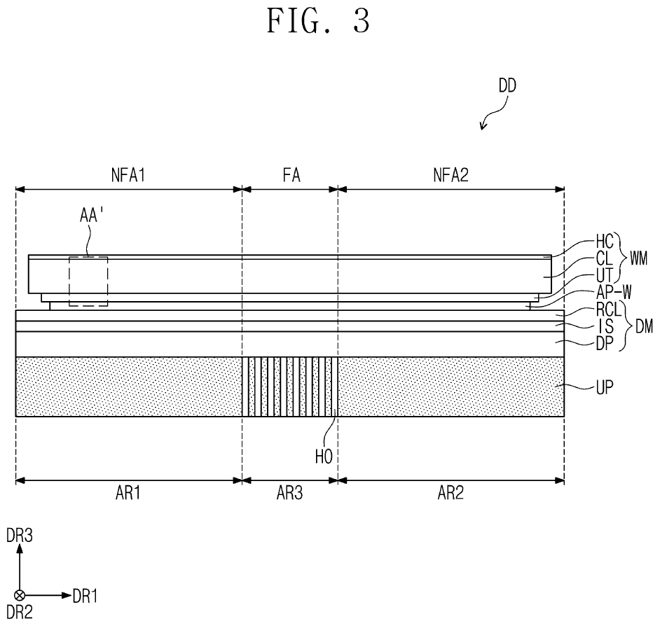

FIG. 3 is a cross-sectional view of a display device DD according to an embodiment. FIG. 3 is a cross-sectional view of the display device DD taken along I-I′ of FIG. 2. FIG. 3 illustrates that the adhesive layer AP illustrated in FIG. 2 is omitted. Referring to FIG. 3, the display device DD may include a window module WM, a display module DM, and a lower plate UP.

A first non-folding region NFA1, a folding region FA, and a second non-folding region NFA2 may be defined along the first direction DR1 in the display device DD. The first non-folding region NFA1, the folding region FA, and the second non-folding region NFA2 defined in the display device DD may be substantially the same as the first non-folding region NFA1, the folding region FA, and the second non-folding region NFA2 of the electronic device ED described with reference to FIG. 1A, or the like.

The window module WM may be disposed on the display module DM. The window module WM may be coupled to the housing HAU (see FIG. 2) to define an exterior of the display device DD, and may protect the display module DM. The window module WM may include a thin-film glass UT and a coating layer CL.

The thin-film glass UT may include a material having a high light transmittance. The thin-film glass UT may be a chemically reinforced glass. The thin-film glass UT may be an ultrathin reinforced glass substrate. Although folding and unfolding are repeated, the thin-film glass UT may minimize generation of a wrinkle therein.

The coating layer CL may be disposed on the thin-film glass UT. The coating layer CL may be disposed on the thin-film glass UT to protect the thin-film glass UT from an external environment. For example, the coating layer CL as a protection layer may protect the thin-film glass UT from an external impact, and may prevent or minimize generation of a scratch on an upper surface of the thin-film glass UT. The coating layer CL may be directly disposed on the thin-film glass UT. That is, the coating layer CL may be coupled to the thin-film glass UT without a separate adhesive layer.

The coating layer CL may include a coating material having an elastic modulus of about 500 megapascals (MPa) to about 3000 MPa. The coating material may be applied on the thin-film glass UT to provide the coating layer CL. The coating layer CL according to an embodiment may be directly formed on the thin-film glass UT to simplify a manufacturing process, and a construction (e.g., a number of parts or layers) of the window module WM.

The window module WM may further include a hard coating layer HC. The hard coating layer HC may be disposed on the coating layer CL to be disposed as the outermost layer of the window module WM. The hard coating layer HC is a functional layer for improving use characteristics of the display device DD, and may be applied on the coating layer CL and be provided. For example, the display device DD may improve anti-fingerprint characteristics, anti-pollution characteristics, anti-reflection characteristics, or anti-scratch characteristics, or the like due to a functional layer such as the hard coating layer HC.

The display module DM may be disposed under the window module WM. The display module DM may display an image IM in response to an electrical signal, and may transmit/receive information about an external input. The display module DM may at least include a display panel DP. The display module DM may include the display panel DP, a sensor layer IS, and a functional layer such as an optical layer RCL.

The display panel DP may be a configuration which substantially generates the image IM. The display panel DP may be a light-emitting display panel, but is not specially limited thereto. For example, the display panel DP may be an organic light-emitting display panel, or an inorganic light-emitting display panel. A light-emitting layer of the organic light-emitting display panel may include an organic light-emitting material. A light-emitting layer of the inorganic light-emitting display panel may include quantum dots, a quantum rod, etc.

The sensor layer IS may be disposed on the display panel DP. The sensor layer IS may include a plurality of sensing electrodes. Accordingly, the sensor layer IS may sense an external input applied from the outside. The external input may be a user's input. The user's input may include external inputs having various forms such as light, heat, or pressure which are applied via an input tool such as a body part of a user.

When the display panel DP is manufactured or provided, the sensor layer IS may be directly formed on the display panel DP through a continuous process. However, an embodiment is not limited thereto, and the sensor layer IS may be separately provided from the display panel DP to be attached to the display panel DP by an intervening layer such as an adhesive layer.

The optical layer RCL may be disposed on the sensor layer IS. The optical layer RCL may be directly disposed on the sensor layer IS. In addition, when the sensor layer IS is omitted in the display module DM, the optical layer RCL may be directly disposed on the display panel DP. However, an embodiment is not limited thereto, and the optical layer RCL may be disposed on the display panel DP or the sensor layer IS using a separate adhesive member as an intervening layer.

The display module DM may be coupled to the window module WM by a window adhesive layer AP-W. The optical layer RCL may function to reduce reflection by external light. The optical layer RCL may reduce reflectance of external light of the display panel DP with respect to light incident on the display panel DP. Although not shown, the optical layer RCL as a light control layer may include at least any one of an anti-reflective layer, a polarization layer, a color filter, or a grey filter.

The lower plate UP may be disposed under the display panel DP. The lower plate UP may be formed or provided by a carrier substrate used in manufacturing the display panel DP. The lower plate UP may be provided as a single layer (e.g., a monolayer), or may include a plurality of layers. An upper surface of the lower plate UP which is closest to the display module DM may be in direct contact with a lower surface of the display panel DP as an outer or lowermost surface of the display module DM. Accordingly, an adhesive layer may be omitted between the lower plate UP and the display panel DP. In this case, a lamination process for coupling the display panel DP and the lower plate UP may be omitted to simplify a process of providing the electronic device ED. However, an embodiment is not limited thereto, and the lower plate UP may be coupled to the display panel DP through the adhesive layer AP (see FIG. 2).

The lower plate UP may protect the display panel DP. For example, the lower plate UP may reduce a stress applied to the display panel DP when the display device DD is folded. In addition, the lower plate UP may prevent external moisture from infiltrating into the display panel DP, and may absorb an external impact.

The lower plate UP may include a first region AR1, a second region AR2, and a third region AR3. That is, the lower plate UP may have the second region AR2 between the first region AR1 and the third region AR3. The first region AR1, the second region AR2, and the third region AR3 of the lower plate UP may be defined along the first direction DR1. The first region AR1 may overlap the first non-folding region NFA1, the second region AR2 may overlap the second non-folding region NFA2, and the third region AR3 may overlap the folding region FA. The first region AR1, the second region AR2, and the third region AR3 may include the same material as each other. For example, the lower plate UP may include a glass substrate as a single, continuous body. When the lower plate UP is provided as a single layer, the lower plate UP may be the glass substrate.

At least one opening (or hole) as a pattern HO may be defined in the lower plate UP. For example, the at least one pattern HO may be defined in the third region AR3 of the lower plate UP. The at least one pattern HO may penetrate a thickness of the lower plate UP from a lower surface of the lower plate UP which is furthest from the display module DM to an upper surface of the lower plate UP which is closest to the display module DM, along the thickness direction. That is, at least one hole may be provided in the third region AR3 of the lower plate UP.

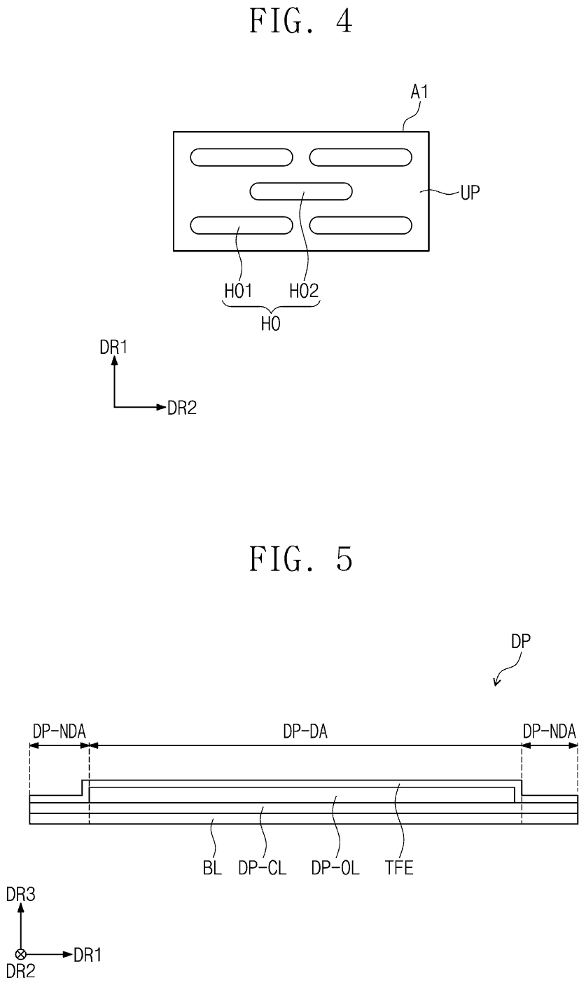

FIG. 4 is a plan view illustrating a display device DD according to an embodiment. FIG. 4 is an enlarged plan view illustrating region A1 of FIG. 2.

Referring to FIG. 4, the pattern HO defined in the lower plate UP may include a hole provided in plural including a plurality of holes HO1 and HO2. Each hole or pattern may extend completely through the thickness of the lower plate UP, such as to be open at both the upper surface and the lower surface of the lower plate UP. In a plan view, the plurality of holes HO1 and HO2 may each extend to have a major planar dimension along the second direction DR2 crossing the first direction DR1, and a minor planar dimension along the first direction DR1. The plurality of holes HO1 and HO2, and may be spaced apart from each other in the first direction DR1 and in the second direction DR2. Each of the holes may be enclosed opening as being defined by solid portions of the lower plate UP.

The plurality of holes HO1 and HO2 may include a first hole HO1 provided in plural including first holes HO1 and a second hole HO2 provided in plural including second holes HO2. The first holes HO1 and the second holes HO2 may each extend to have a major planar dimension along the second direction DR2. The first holes HO1 may be spaced apart from each other in the second direction DR2. The first holes HO1 may be arranged in the second direction DR2 to form a first group of holes. The second holes HO2 may be spaced from the first holes HO1 in the first direction DR1. The second holes HO2 may be spaced from each other in the second direction DR2 to form a second group of holes. The first holes HO1 of the first group and the second holes HO2 of the second group may be arranged staggered with each other along the first direction DR1.

FIG. 5 is a cross-sectional view of a display panel DP according to an embodiment. Referring to FIG. 5, the display panel DP may include a base layer BL, a circuit layer DP-CL, a display element layer DP-OL, and an encapsulation layer TFE.

The base layer BL may provide a base surface on which the circuit layer DP-CL is disposed. The base layer BL may be provided as a rigid substrate, but is not limited thereto, and may be provided as a flexible substrate. The base layer BL may include a display region DP-DA and a non-display region DP-NDA. The non-display region DP-NDA may be a region in which a driving circuit or driving line for driving elements disposed in the display region DP-DA, various signal lines supplying an electrical signal, pads, etc., are disposed.

The circuit layer DP-CL may be disposed on the base layer BL. The circuit layer DP-CL may include at least one insulating layer, driving elements, signal lines, and signal pads.

The display element layer DP-OL may be disposed on the circuit layer DP-CL. The display element layer DP-OL may include light-emitting elements disposed overlapping the display region DP-DA. The light-emitting elements of the display element layer DP-OL may be electrically connected to driving elements of the circuit layer DP-CL to supply source light in response to a signal of the driving elements.

The encapsulation layer TFE may be disposed on the display element layer DP-OL to seal the light-emitting elements. The encapsulation layer TFE may include a plurality of insulating films. The insulating films of the encapsulation layer TFE may be disposed so as to improve optical efficiency of the light-emitting element or to protect the light-emitting element.

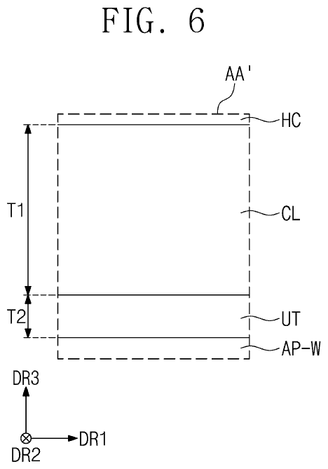

FIG. 6 is a cross-sectional view illustrating some configurations of a display device according to an embodiment. FIG. 6 is an enlarged cross-sectional view illustrating region AA′ of FIG. 3.

Referring to FIGS. 3 and 6, a first thickness T1 of the coating layer CL may be equal to or less than about 110 micrometers (μm). The first thickness T1 of the coating layer CL may be about 50 μm to about 110 μm, about 50 μm to about 60 μm, about 50 μm to about 80 μm, about 90 μm to about 110 μm, about 80 μm to about 100 μm, or about 70 μm to about 90 μm, but an embodiment is not limited thereto. For example, the coating layer CL may have a first thickness T1, of about 80 μm to about 100 μm, capable of ensuring all of a folding function and an impact resistance.

When the first thickness T1 of the coating layer CL is less than the range described above, support ability of the coating layer CL may be deteriorated to increase strain of the thin-film glass UT. When the first thickness T1 of the coating layer CL is more than the range described above, folding characteristics may be deteriorated.

A second thickness T2 of the thin-film glass UT may be small. For example, the second thickness T2 of the thin-film glass UT may be smaller than the first thickness T1 of the coating layer CL. The second thickness T2 of the thin-film glass UT is not specially limited, but may be about 20 μm to about 100 μm, or may be about 30 μm.

The coating layer CL may have an elastic modulus of about 500 MPa to about 3000 MPa, about 500 MPa to about 2000 MPa, 500 MPa to about 1000 MPa, or about 1000 MPa to about 2000 MPa. When the elastic modulus of the coating layer CL is in the range described above, the coating layer CL may show stable folding characteristics. When the elastic modulus of the coating layer CL is less than about 500 MPa, buckling may occur due to a compressive strass applied on the coating layer CL, and thus folding characteristics of the coating layer CL may be remarkably deteriorated. When the elastic modulus of the coating layer CL is more than about 3000 MPa to be too high, a repulsive force may increase so that folding characteristics of the coating layer CL may be deteriorated, and thus there may be a strong possibility that a crack will occur in the thin-film glass UT.

In the display device DD in which the lower plate UP according to an embodiment is disposed under the display module DM, the coating layer CL may have a first elastic modulus equal to or more than about 500 MPa and less than about 2000 MPa. Here, for the display device DD in which the lower plate UP is disposed under the display module DM, the coating layer CL has the first elastic modulus together with the first thickness T1 being about 80 μm to about 100 μm.

In the display device DD according to an embodiment, the coating layer CL may have a second elastic modulus of about 500 MPa to about 1000 MPa. Here, for the display device DD in which the lower plate UP is disposed under the display module DM, the coating layer CL has the second elastic modulus together with the first thickness T1 of the coating layer CL being about 90 μm to about 110 μm. The display device DD according to an embodiment may include the coating layer CL having the second elastic modulus in the thickness of about 90 μm to about 110 μm so that a torque of the display module DM may be equal to or less than about 150 newton millimeters (N·mm), and a strain of the thin-film glass UT may be equal to or less than about 1.3%. Such torque may be defined for a folding operation of the display device DD. Accordingly, the display device DD according to an embodiment may show excellent folding characteristics and impact resistance. When the coating layer CL has the elastic modulus less than about 500 MPa in the thickness of about 90 μm to about 110 μm, buckling may occur due to a compressive stress applied onto the coating layer CL, and thus folding characteristics may be deteriorated. In addition, when the coating layer CL has an elastic modulus more than about 1000 MPa in the thickness of about 90 μm to about 110 μm, folding characteristics may be deteriorated due to increase in a repulsive force, and a crack may occur in the thin-film glass UT.

The first thickness T1, described above, of the coating layer CL may be changed according to a change of the elastic modulus thereof. For example, the first thickness T1 of the coating layer CL may decrease due to increase in the elastic modulus thereof. The coating layer CL according to an embodiment may have a larger elastic modulus than the second elastic modulus, and in this case, the first thickness T1 of the coating layer CL may be smaller than the first thickness T1 of the coating layer CL which corresponds to the second elastic modulus. In order to show stable folding characteristics, when the elastic modulus becomes higher than the second elastic modulus by about 1000 MPa, the first thickness T1 of the coating layer CL may become smaller than the first thickness corresponding to the second elastic modulus by about 20 μm,. In this case, the coating layer CL may be stably folded.

In an embodiment, the coating layer CL may have a third elastic modulus more than about 1000 MPa and equal to or less than about 2000 MPa. The coating layer CL may have a third thickness equal to or more than about 70 μm and less than about 90 μm which corresponds to the third elastic modulus. The coating layer CL may have a thickness, equal to or more than about 70 μm and less than about 90 μm, smaller than the thickness (about 90 μm to about 110 μm) in the second elastic modulus, as corresponding to the third elastic modulus greater than the second elastic modulus. For example, when the coating layer CL has the third elastic modulus of about 2000 MPa, the third thickness of the coating layer CL may be about 80 μm. Here, for the display device DD in which the lower plate UP is disposed under the display module DM, the coating layer CL may have the third elastic modulus greater than the second elastic modulus together with the third thickness of about 70 μm to about 90 μm.

In addition, the coating layer CL according to an embodiment may have a fourth elastic modulus more than about 2000 MPa and equal to or less than about 3000 MPa. For example, when the fourth elastic modulus of the coating layer CL is about 3000 MPa, the coating layer CL may have a fourth thickness smaller than the third thickness corresponding to the third elastic modulus. The coating layer CL may have a fourth thickness equal to or more than about 50 μm and less than about 70 μm, or equal to or more than about 50 μm and equal to or less than about 60 μm. That is, for the display device DD in which the lower plate UP is disposed under the display module DM, the coating layer CL may have the fourth elastic modulus larger than the second and third elastic moduli, together with the fourth thickness of about 50 μm to about 60 μm.

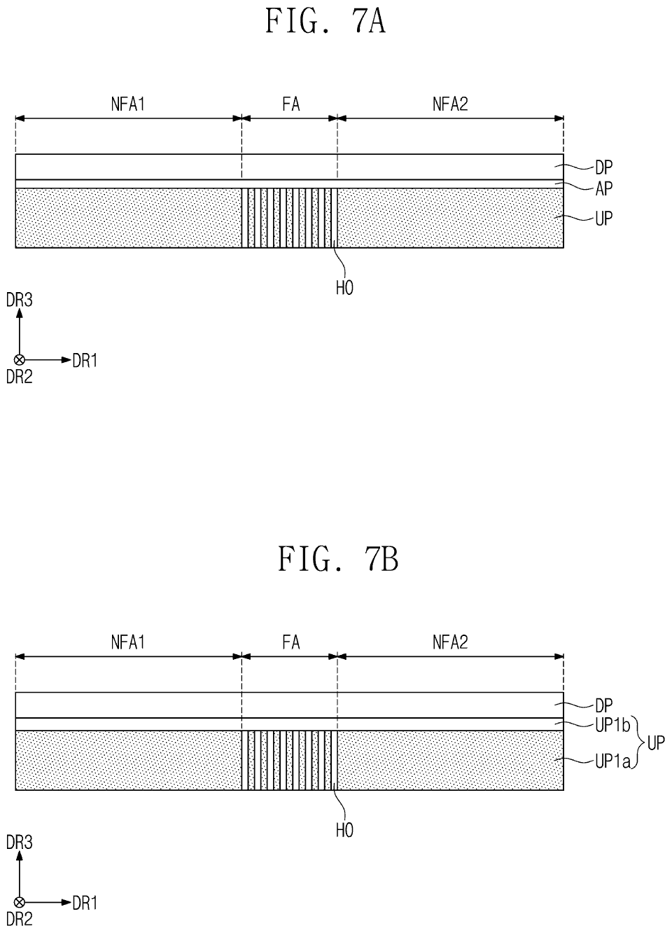

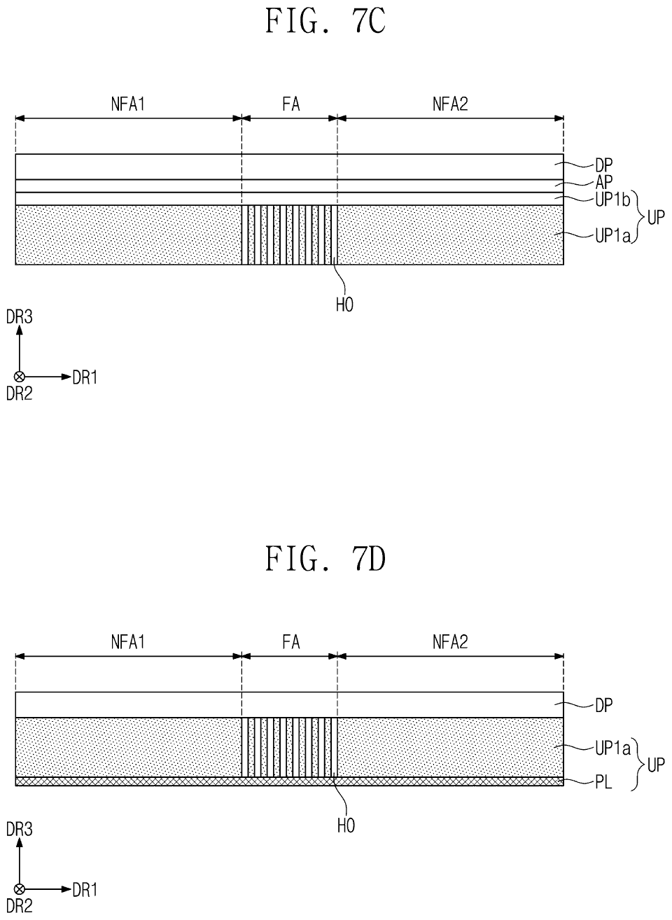

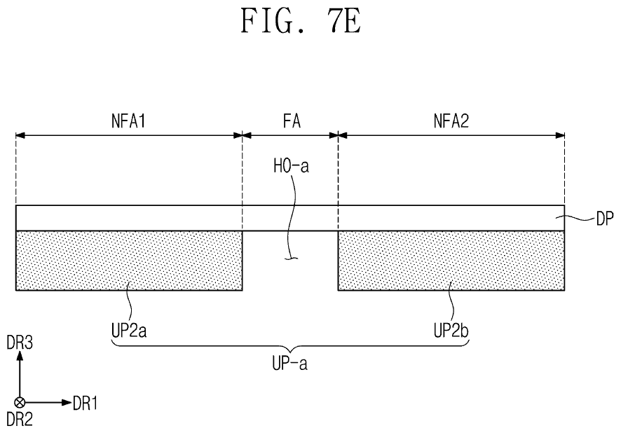

FIGS. 7A to 7E are respectively cross-sectional views illustrating a display device according to embodiments. FIG. 7A illustrates a display panel DP and a lower plate UP among the configurations of the display device DD according to an embodiment. FIGS. 7B to 7E respectively illustrate other embodiments of lower plates UP including sub-plates or sub-layers according to an embodiments. Each of the lower plates UP or the lower sub-plate UP-a described with reference to FIGS. 7A to 7E may be substituted for the lower plate UP of FIG. 3 to be applied to a display device DD.

Referring to FIG. 7A, an adhesive layer AP may be included between the lower plate UP and the display panel DP. The lower plate UP may be coupled to the display panel DP through the adhesive layer AP.

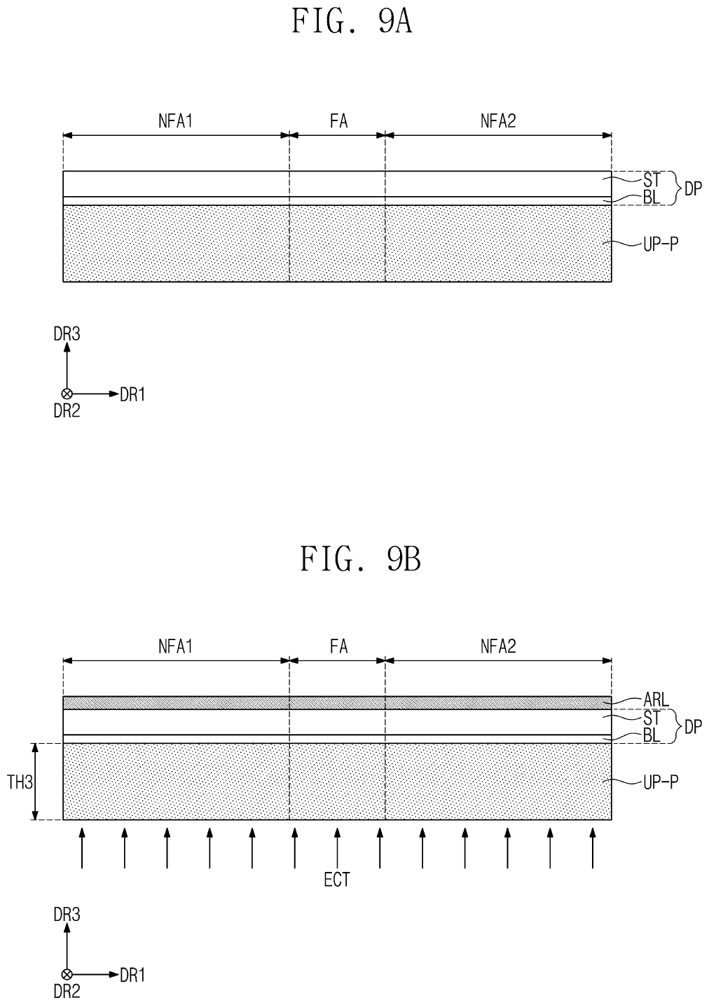

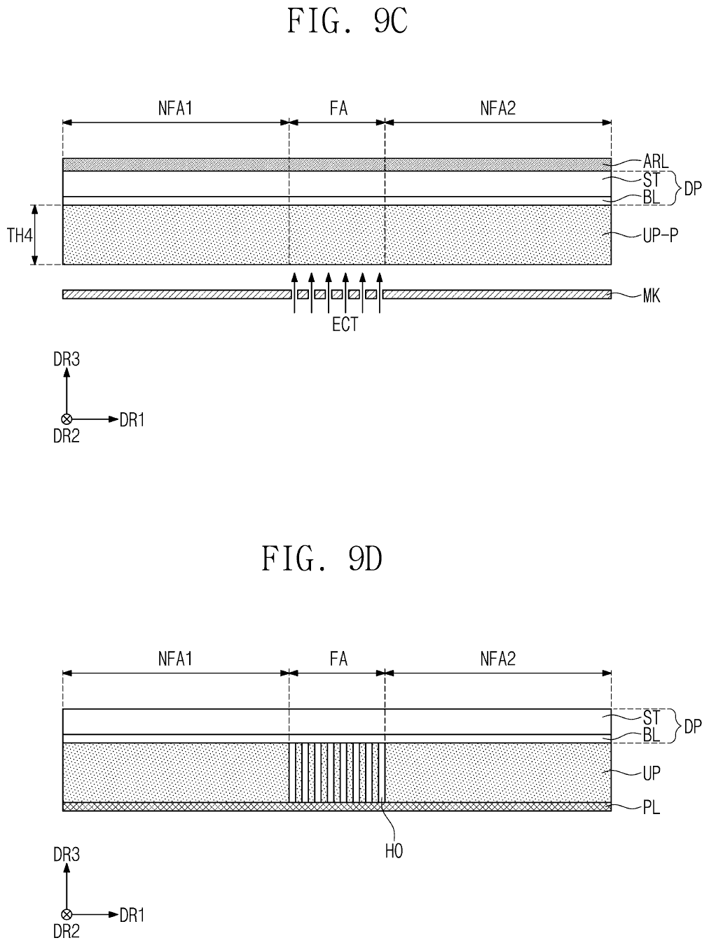

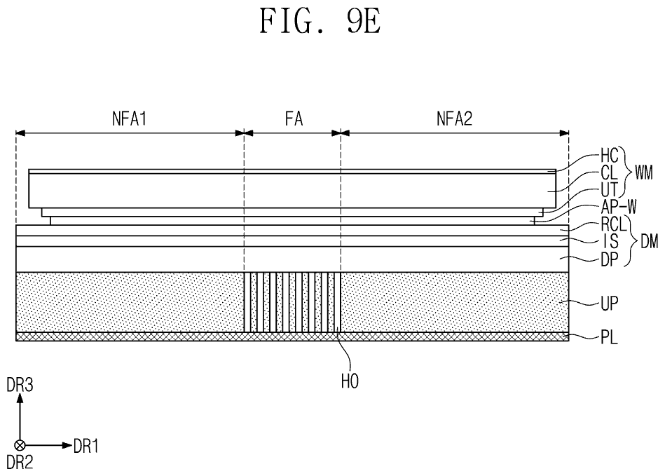

A plurality of patterns HO may be defined in the lower plate UP. On a plane, the plurality of patterns HO may overlap a folding region FA. The plurality of patterns HO may penetrate from a lower surface of the lower plate UP toward an upper surface of the lower plate UP, such as to be open at both the upper and lower surfaces thereof, without being limited thereto. In addition, the protective layer PL (see FIGS. 7D, 9E, and the like) capable of protecting the display panel DP from an external impact, or the like may be provided on the lower surface of the lower plate UP.

Referring to FIGS. 7B to 7D, the lower plate UP according to an embodiment may include a plurality of layers. For example, as illustrated in FIGS. 7B and 7C, the lower plate UP may include a base substrate UP1a and a functional layer UP1b. As illustrated in FIG. 7D, the lower plate UP may include the base substrate UP1a and a protective layer PL. Although not shown, the lower plate UP may include all of the functional layer UP1b, the base substrate UP1a, and the protective layer PL.

The upper surface of the lower plate UP which is closest to the display panel DP may be in direct contact with a lower surface of the display panel DP which is closest to the lower plate UP, along a thickness direction (refer to FIGS. 7B and 7D). As used herein, elements which are in contact with each other may form an interface therebetween. In addition, the lower plate UP may be coupled to a lower portion of the display panel DP by the adhesive layer AP (refer to FIG. 7C).

The base substrate UP1a may include a rigid material. The base substrate UP1a may include glass. The base substrate UP1a may be a glass substrate. At least one pattern HO may be defined in the base substrate UP1a. For example, a plurality of patterns HO overlapping the folding region FA may be defined in the base substrate UP1a. Each of the plurality of patterns HO may penetrate from a lower surface of the base substrate UP1a toward an upper surface of the base substrate UP1a.

The functional layer UP1b as a plate functional layer may be disposed on the upper surface of the base substrate UP1a. The functional layer UP1b may be directly disposed on the upper surface of the base substrate UP1a to act as an etching stopper in a process of forming the plurality of patterns HO in a body of the base substrate UP1a. That is, the functional layer UP1b may be an etching stopper layer. In addition, the functional layer UP1b may serve to improving an adhesive force between the display panel DP and the lower plate UP. The functional layer UP1b may include a material having a low reactivity for an etching solution used in forming the plurality of patterns HO. Accordingly, when the functional layer UP1b is provided, damage of the display panel DP may be prevented during formation of the plurality of patterns HO, and shape accuracy of the plurality of patterns HO may be improved.

The protective layer PL may be disposed on the lower surface of the base substrate UP1a which is furthest from the display panel DP. An upper surface of the protective layer PL may be in direct contact with the lower surface of the base substrate UP1a. The protective layer PL may include an adhesive material and/or a flexible material. The protective layer PL may protect the base substrate UP1a and the display panel DP from an external impact, or the like. Accordingly, the display device DD in which the protective layer PL is provided may have an excellent impact resistance.

Referring to FIG. 7E, the lower plate UP-a may include plate portions such as first and second lower plates UP2a and UP2b respectively corresponding to non-folding regions NFA1 and NFA2. For example, the lower plate UP-a may include a first lower plate UP2a corresponding to the first non-folding region NFA1 and a second lower plate UP2b corresponding to the second non-folding region NFA2. The first and second lower plates UP2a and UP2b may include glass. The first and second lower plates UP2a and UP2b may be each a glass substrate.

One single, continuous pattern HO-a may be defined in a body of the lower plate UP-a. For example, the pattern HO-a overlapping the folding region FA may be defined in the body of the lower plate UP-a. The pattern HO-a may penetrate from a lower surface of the lower plate UP-a toward an upper surface of the lower plate UP-a. Accordingly, the first lower plate UP2a and the second lower plate UP2b may be spaced apart from each other by the folding region FA. Here, the plate portions may be disconnected from each other by the pattern HO-a. The first and second lower plates UP2a and UP2b may be disposed spaced apart from each other in the first direction DR1. The first and second lower plates UP2a and UP2b may not overlap the folding region FA, or unlike what is illustrated, may partially overlap the folding region FA.

The lower plate UP-a may further include a connection module for connecting the first and second lower plates UP2a and UP2b to each other. The connection module may include a hinge module or an articulated module.

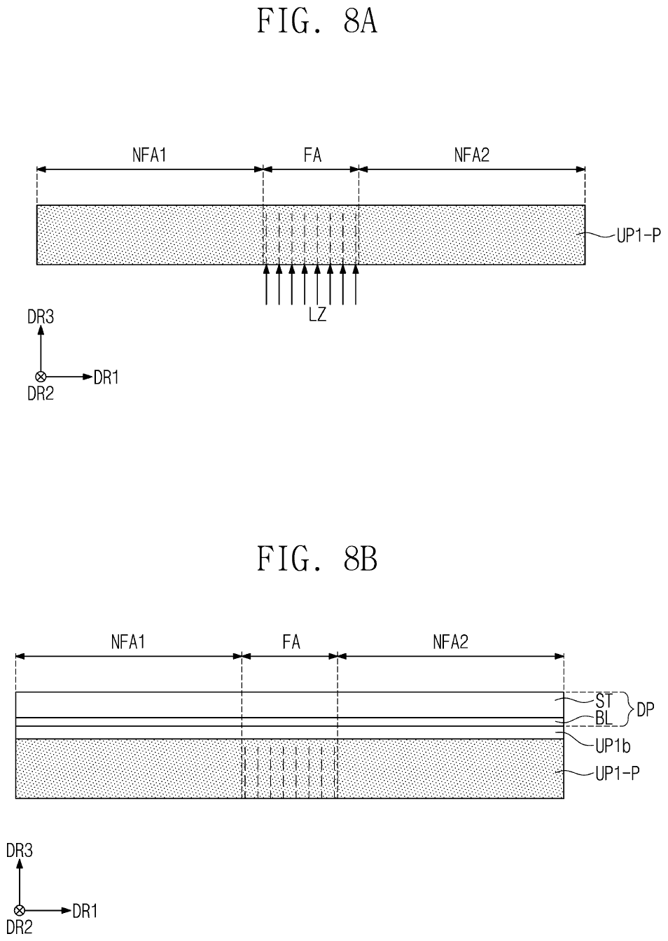

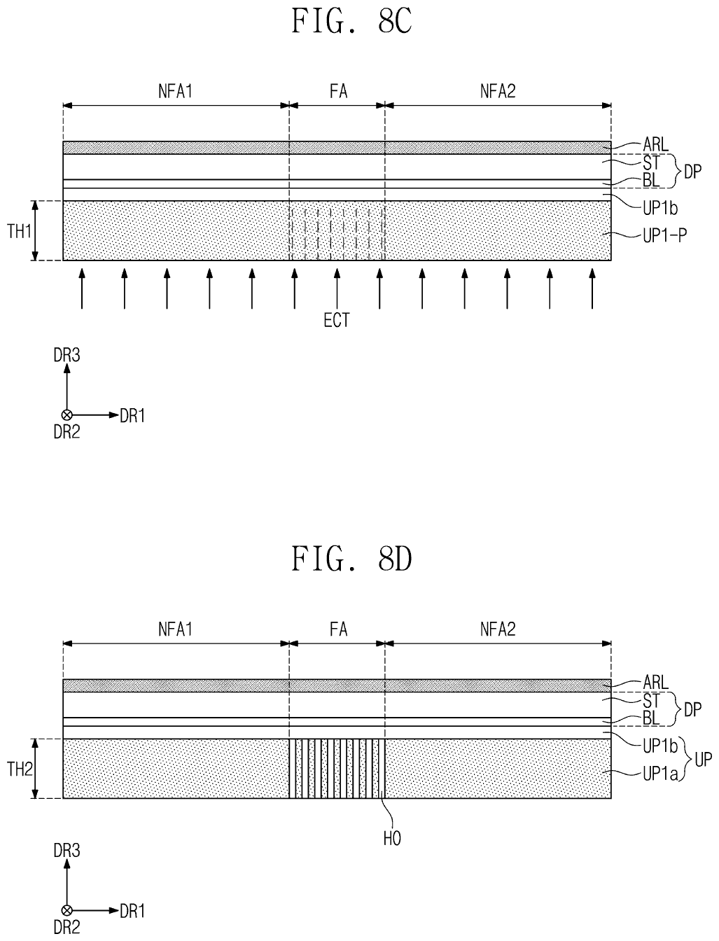

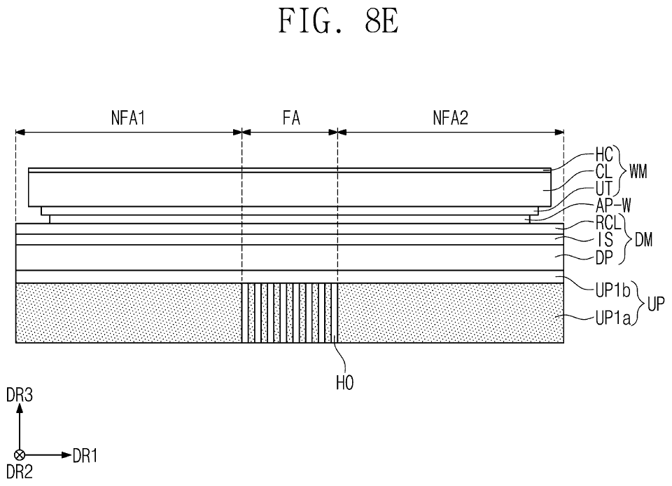

FIGS. 8A to 8E are cross-sectional views illustrating processes of a method for manufacturing (or providing) a display device according to an embodiment. Each of FIGS. 8A to 8D are for describing an operation of forming a lower plate UP according to an embodiment and an operation of forming a display panel DP. FIG. 8E is for describing an operation of forming a window module WM on a display panel DP. In describing FIGS. 8A to 8E, the same/similar configurations are described using the same/similar reference numerals or symbols with reference to FIGS. 2 to 7E, and duplicate description thereof will be omitted.

The method for manufacturing (or providing) a display device DD according to an embodiment may include the operation of forming (or providing) a lower plate UP, the operation of forming a display panel DP, and the operation of forming a window module WM. The operation of forming a lower plate UP may include an operation of irradiating laser, an operation of providing an acid-resistant layer, and an etching operation. The operation of irradiating laser will be described with reference to FIGS. 8A and 8B, and the operation of providing an acid-resistant layer and the etching operation will be described with reference to FIGS. 8C and 8D.

Referring to FIGS. 8A and 8B first, a preliminary lower plate UP1-P may be prepared, and laser LZ may be irradiated on the preliminary lower plate UP1-P. The laser LZ may be irradiated at one surface of the prepared preliminary lower plate UP1-P at a location overlapping the folding region FA, and may not be irradiated to the preliminary lower plate UP1-P at locations overlapping the non-folding regions NFA1 and NFA2. The region on which the laser LZ is irradiated may be a region corresponding to a pattern HO (see FIG. 8E) of the lower plate UP (see FIG. 8E) to be described later.

Referring to the dotted lines in FIG. 8A, the laser LZ penetrates a partial thickness of the preliminary lower plate UP1-P. The partial penetration provides preliminary holes or patterns extended from a lower surface of the preliminary lower plate UP1-1. Here, a body of the preliminary lower plate UP1-1 may be penetrated at positions along the folding region FA, such as to be open at the lower surface. A thickness portion of the preliminary lower plate UP1-1 may remain above the preliminary holes or patterns, to define an upper surface of the preliminary lower plate UP1-1.

Thereafter, referring to FIG. 7B, a display panel DP may be formed on the other surface of the preliminary lower plate UP1-P opposing the surface on which the laser LZ is irradiated (e.g., the upper surface at which the preliminary holes or patterns are not open to outside the preliminary lower plate UP1-1. Hereinafter, the one surface of the preliminary lower plate UP1-P, which is the surface on which the laser LZ is irradiated, may be referred to as a lower surface of the preliminary lower plate UP1-P, and the other surface of the preliminary lower plate UP1-P may be referred to as an upper surface of the preliminary lower plate UP1-P.

In an embodiment, before forming of the display panel DP, a functional layer UP1b may be formed on the upper surface of the preliminary lower plate UP1-P. The functional layer UP1b may be an etching stopper layer for protecting the display panel DP in an etching process to be described later. Unlike what is illustrated, a process of forming the functional layer UP1b may be omitted. In this case, the lower plate UP (see FIG. 7A), having a single layer, may be formed from the preliminary lower plate UP1-P.

Thereafter, a base layer BL is formed by applying a layer of a base material on the upper surface of the functional layer UP1b. In some embodiments, the base layer BL may be formed by forming an adhesive layer AP on the upper surface of the functional layer UP1b, and applying the base material on an upper surface of the adhesive layer AP (see FIG. 7C).

A stack structure ST of the display panel DP may be formed on the base layer BL. The stack structure ST may include the circuit layer DP-CL (see FIG. 5), the display element layer DP-OL (see FIG. 5), and the encapsulation layer TFE (see FIG. 5) of the display panel DP. For example, the circuit layer DP-CL may be formed on the base layer BL, the display element layer DP-OL may be formed on the circuit layer DP-CL, and the encapsulation layer TFE covering the display element layer DP-OL may be formed on the display element layer DP-OL to constitute the display panel DP. The display panel DP may be formed on the functional layer UP1b.

Unlike what is illustrated, the base layer BL may be directly formed on the upper surface of the preliminary lower plate UP1-P. Accordingly, a process of forming the functional layer UP1b between the display panel DP and the preliminary lower plate UP1-P may be omitted. The base layer BL may be in direct contact with the upper surface of the preliminary lower plate UP1-P. In addition, when the adhesive layer AP (see FIG. 7C) is formed on the upper surface of the preliminary lower plate UP1-P, the base layer BL may be formed on the upper surface of the adhesive layer AP.

Referring to FIGS. 8C and 8D, an acid-resistant layer ARL covering the display panel DP may be provided on the display panel DP. Before etching the preliminary lower plate UP1-P to provide the pattern HO, the acid-resistant layer ARL may be provided on the upper surface of the display panel DP. The acid-resistant layer ARL may include an acid-resistant material. The acid-resistant layer ARL may be used so as to protect the display panel DP, or the like from an etching solution ECT, and may be used without limitation as long as being easily removed after the etching operation. The acid-resistant layer ARL may be formed by attaching an acid-resistant film on the upper surface of the display panel DP, and may be provided by applying the acid-resistant material on the upper surface of the display panel DP.

Referring to FIGS. 8C and 8D, the etching solution ECT is supplied to the preliminary lower plate UP1-P. The etching solution ECT may be supplied to a partial thickness of the preliminary lower plate UP1-P having the preliminary holes or patterns therein. Material portions (e.g., volumes) of the preliminary lower plate UP1-P may be partially removed by the etching solution ECT penetrating into a thickness portion of the body of the preliminary lower plate UP1-P at the preliminary holes or patterns. Accordingly, a preliminary thickness TH1 of the preliminary lower plate UP1-P may be reduced, and a pattern HO (see FIG. 8E) may be formed in a portion on which the laser LZ (see FIG. 8A) is irradiated by the removal of the material volumes. After the etching operation, a total thickness TH2 of the lower plate UP may be smaller than the preliminary thickness TH1 of the preliminary lower plate UP1-P.

In the etching operation, the etching solution ECT may be supplied to the entire lower surface of the preliminary lower plate UP1-P, as indicated in FIG. 8C by the upward arrows. When the etching solution ECT is supplied to the entire lower surface of the preliminary lower plate UP1-P, an original thickness of the preliminary lower plate UP1-P may be reduced due to the etching solution ECT applied across an entirety of the lower surface of the preliminary lower plate UP1-P. In addition, the region, of the preliminary lower plate UP1-P, on which the laser LZ is irradiated may have a greater etch rate than the region, of the preliminary lower plate UP1-P, on which the laser LZ is not irradiated, such as owing to the preliminary holes or patterns. Accordingly, material volumes at a location of the preliminary lower plate UP1-P at which the laser LZ is irradiated may be more rapidly removed by the etching solution ECT than at locations on which the laser LZ is not irradiated. Thus, the patterns HO may be formed in the preliminary lower plate UP1-P from the region of the preliminary lower plate UP1-P at which the laser LZ is irradiated.

The patterns HO may be formed in a portion of the preliminary lower plate UP1-P overlapping the folding region FA, and may correspond a plurality of holes penetrating the lower plate UP in a thickness direction. That is, the patterns HO may correspond penetration holes which extend from the lower surface of the lower plate UP to the upper surface of the lower plate UP to be open at both the lower and upper surfaces.

In addition, the etching solution ECT may be selectively supplied only to the lower surface of the preliminary lower plate UP1-P corresponding the folding region FA, different from the etching solution ECT being supplied to the entire lower surface of the preliminary lower plate UP1-P. For example, a mask may be disposed under the preliminary lower plate UP1-P, and the etching solution ECT may be selectively supplied only to a portion, of the preliminary lower plate UP1-P, on which the laser LZ is irradiated through the mask. After the etching operation, the base substrate UP1a in which the patterns HO are defined may be formed from the preliminary lower plate UP1-P.

Referring to FIGS. 8D and 8E, the patterns HO may be finally formed through the etching operation in a state in which the acid-resistant layer ARL (see FIG. 8C) is on the stacked structure including the display panel DP and the lower plate UP, and then the acid-resistant layer ARL may be removed. A sensor layer IS and an optical layer RCL may be sequentially formed on the display panel DP within the stacked structure from which the acid-resistant layer ARL is removed, to provide the display module DM. The window module WM including the coating layer CL according to an embodiment may be formed on the optical layer RCL of the display module DM. A window adhesive layer AP-W may be formed by supplying an optically clear adhesive (OCA) film or an optically clear adhesive resin (OCR) layer on the display module DM. The window adhesive layer AP-W may couple the window module WM and the display module DM to each other.

The operation of forming the window module WM may include an operation of forming a thin-film glass UT and an operation of forming a coating layer CL, and may further include an operation of forming a hard coating layer HC. For example, in the window module WM, the thin-film glass UT may be formed on the display module DM as an underlying layer, the coating layer CL may be formed on the thin-film glass UT, and the hard coating layer HC may be formed on the coating layer CL to finally form the window module WM.

The coating layer CL according to an embodiment may be formed by supplying a coating material on an upper surface of the thin-film glass UT. The coating layer CL may be directly formed on the thin-film glass UT without a separate adhesive layer to simplify a manufacturing process. The coating layer CL may be formed by supplying the coating material on the upper surface of the thin-film glass UT with a thickness of about 50 μm to about 110 μm. The coating material may include a material having an elastic modulus of about 500 MPa to about 3000 MPa. Accordingly, the coating layer CL may show stable folding characteristics. In addition, when the coating layer CL has the elastic modulus of about 500 MPa to about 3000 MPa together with a thickness of about 50 μm to 110 μm, particularly about 80 μm to about 100 μm, the coating layer CL may simultaneously show stable folding characteristics and an excellent impact resistance.

The coating material may be supplied in an inkjet printing method or dispensing method. The coating material may be supplied in a constant amount and/or at a constant speed.

A thickness of the coating layer CL may be changed according to an elastic modulus thereof. For example, the coating layer CL may have a thickness of about 80 μm to about 100 μm together with a first elastic modulus equal to or more than about 500 MPa and less than about 2000 MPa. In addition, the coating layer CL may have a thickness of about 90 μm to about 110 μm together with a second elastic modulus equal to or more than about 500 MPa and less than about 1000 MPa, and may have a thickness of about 70 μm to about 90 μm together with a third elastic modulus more than about 1000 MPa and equal to or less than about 2000 MPa.

FIGS. 9A to 9E are cross-sectional views illustrating processes of a method for manufacturing a display device DD according to an embodiment. In describing FIGS. 9A to 9E, the same/similar configurations are described using the same/similar reference numerals or symbols with reference to FIGS. 2 to 8E, and duplicate description thereof will be omitted. The method for manufacturing a display device DD described with reference to FIGS. 8A to 8E and the method for manufacturing a display device DD described with reference to FIGS. 9A to 9E have a difference in an operation of forming a lower plate UP. For example, the operation of forming a lower plate may include an operation of providing an acid-resistant layer and an etching operation, and an operation of irradiating laser may be omitted. In addition, the operation of forming a lower plate may further include an operation of forming a preventive layer.

Referring to FIG. 9A, a display panel DP may be formed on a preliminary lower plate UP-P. For example, a base layer BL may be formed by applying a base material on an upper surface of the preliminary lower plate UP-P, and a stack structure ST may be formed on the base layer BL. However, an embodiment is not limited thereto, and the adhesive layer AP (see FIG. 2) may be formed on the upper surface of the preliminary lower plate UP-P, and the display panel DP may be formed on the adhesive layer AP. In addition, unlike what is illustrated, a functional layer UP1b (see FIG. 8B, or the like) may be formed on the upper surface of the preliminary lower plate UP-P, and then the display panel DP may be formed on an upper surface of the functional layer UP1b. A process of forming the display panel DP may be the same as the process described with reference to FIG. 8B.

Referring to FIGS. 9B and 9C, an acid-resistant layer ARL covering the display panel DP may be provided on the display panel DP, and then the preliminary lower plate UP-P may be at least partially etched. The etching operation may include a first etching operation of reducing a preliminary thickness of (e.g., slimming) the preliminary lower plate UP-P and a second etching operation of forming the pattern HO (see FIG. 9D) in the preliminary lower plate UP-P having the reduced thickness.

In the first etching operation, the etching solution ECT may be entirely supplied to a lower surface of the preliminary lower plate UP-P. Accordingly, the preliminary lower plate UP-P may get thinner. Accordingly, the preliminary lower plate UP-P on which the first etching operation is performed may be thinner than the preliminary lower plate UP-P on which the first etching operation is not performed.

In the second etching operation, the etching solution ECT may be supplied only to a lower surface of the preliminary lower plate UP-P corresponding to the folding region FA. For example, a mask MK in which at least one hole is defined in a region overlapping the folding region FA may be disposed under the preliminary lower plate UP-P. The etching solution ECT may be supplied to the preliminary lower plate UP-P through holes defined in the mask MK, and the patterns HO may be formed from a portion to which the etching solution ECT is supplied. Accordingly, after the first and second etching operations, the preliminary lower plate UP-P may be changed to a form of the lower plate UP having a reduced thickness and the patterns HO defined therein. The lower plate UP which is finally formed may overlap the first and second non-folding regions NFA1 and NFA2 and the folding region FA.

Referring to FIG. 9D, in a state in which the acid-resistant layer ARL is formed, the patterns HO may be formed through the etching operation, and then the acid-resistant layer ARL may be removed. The operation of forming the acid-resistant layer ARL on the display panel DP may be substantially the same as the process described with reference to FIGS. 8C and 8D.

The method for manufacturing a display device DD according to an embodiment may further include the operation of forming the protective layer PL. The protective layer PL may be supplied to an entirety of a lower surface of the lower plate UP. The operation of forming the protective layer PL may be performed after the etching operation, and before or after removing the acid-resistant layer ARL.

Referring to FIG. 9E, a sensor layer IS and an optical layer RCL may be sequentially formed on the display panel DP from which the acid-resistant layer ARL (see FIG. 9C) is removed, and a window module WM including a coating layer CL according to an embodiment may be formed on the optical layer RCL. An optically clear adhesive film or optically clear adhesive resin layer may be supplied on the display module DM to form a window adhesive layer AP-W. The process of forming the window module WM of FIG. 9E may be substantially the same as the process of forming the window module WM described with reference to FIGS. 8D and 8E.

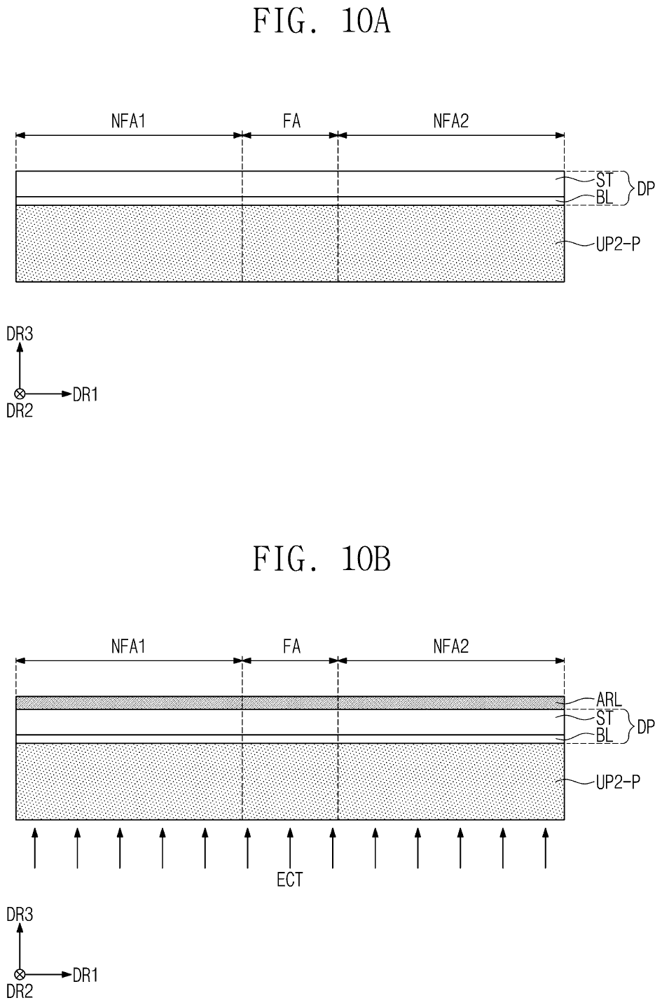

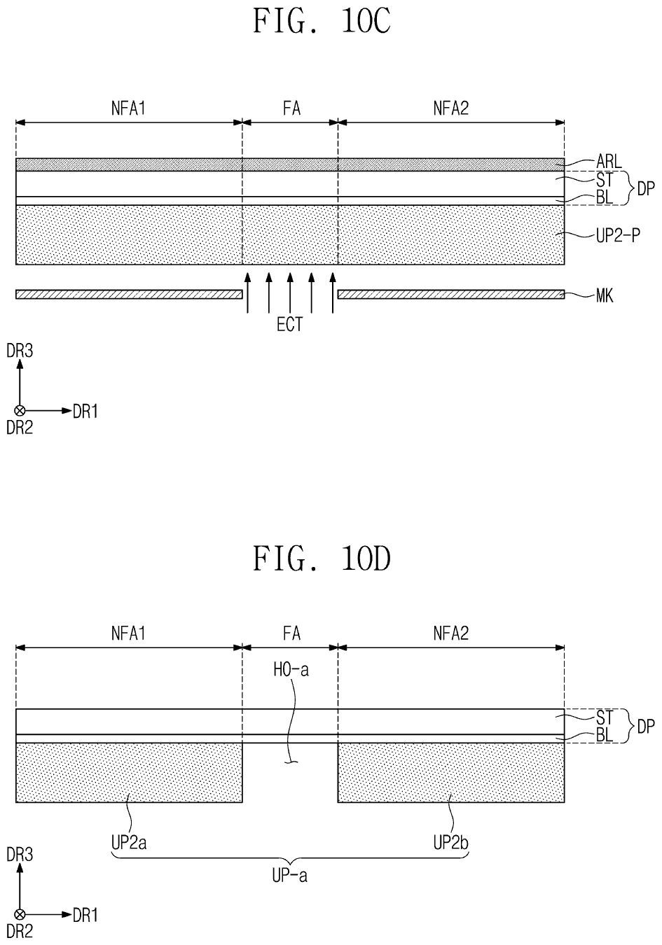

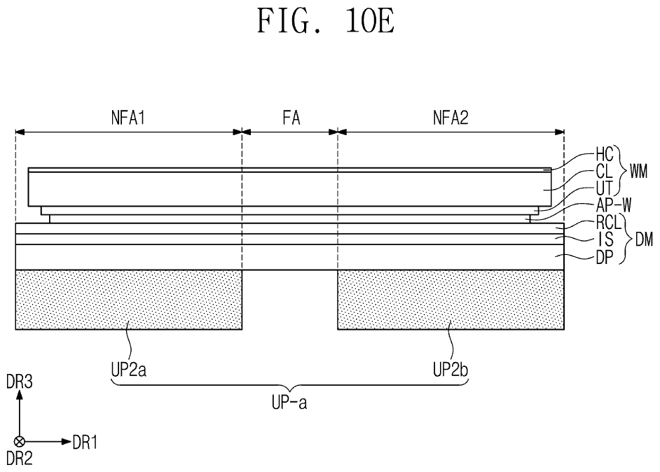

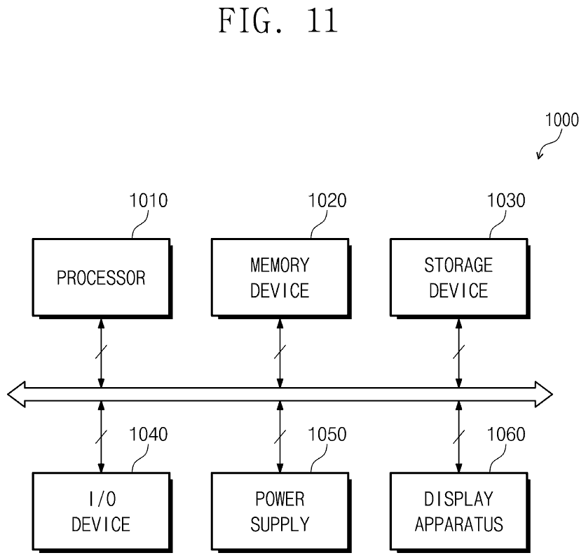

FIGS. 10A to 10E are cross-sectional views illustrating processes of a method for manufacturing a display device DD according to an embodiment. In describing FIGS. 10A to 10E, the same/similar configurations are described using the same/similar reference numerals or symbols with reference to FIGS. 2 to 9E, and duplicate description thereof will be omitted. The method for manufacturing a display device DD described with reference to FIGS. 10A to 10E and the method for manufacturing a display device DD described with reference to FIGS. 8A to 8E have a difference in the operation of forming a lower plate. For example, the operation of forming a lower plate may include the operation of providing an acid-resistant layer and the etching operation, and the operation of irradiating laser may be omitted. In addition, there is a difference in structures of lower plates formed according to an embodiment.

Referring to FIG. 10A, a display panel DP may be formed on a preliminary lower plate UP2-P. For example, a base layer BL may be formed by applying a base material on an upper surface of the preliminary lower plate UP2-P, and a stack structure ST may be formed on the base layer BL. However, an embodiment is not limited thereto, and an adhesive layer AP (see FIG. 7C) may be formed on the upper surface of the preliminary lower plate UP2-P, and the display panel DP may be formed on the adhesive layer AP. In addition, unlike what is illustrated, the functional layer UP1b (see FIG. 8B, or the like) may be formed on the upper surface of the preliminary lower plate UP2-P, and then the display panel DP may be formed on an upper surface of the functional layer UP1b. A process of forming the display panel DP may be the same as the process described with reference to FIG. 8B.

Referring to FIGS. 10B and 10C, an acid-resistant layer ARL covering the display panel DP may be provided on the display panel DP, and then the preliminary lower plate UP2-P may be at least partially etched. The etching operation may include a first etching operation of slimming the preliminary lower plate UP2-P and a second etching operation of forming the pattern HO-a (see FIG. 10D) in the preliminary lower plate UP2-P.

In the first etching operation, an etching solution ECT may be supplied to an entirety of a lower surface of the preliminary lower plate UP2-P. Accordingly, the preliminary lower plate UP2-P may become thin. Accordingly, the preliminary lower plate UP2-P on which the first etching operation is performed may be thinner than a preliminary thickness of the preliminary lower plate UP2-P on which the first etching operation is not performed.

In the second etching operation, the etching solution ECT may be supplied only to the lower surface of the preliminary lower plate UP2-P corresponding to a folding region FA. For example, a mask MK in which only one hole overlapping the folding region FA is defined may be disposed under the preliminary lower plate UP2-P. The etching solution ECT may be supplied to the preliminary lower plate UP2-P through the hole defined in the mask MK, and the pattern HO-a may be formed from a portion to which the etching solution ECT is supplied. The pattern HO-a may be formed in a portion overlapping the folding region FA, and may correspond to one penetration hole penetrating from a lower surface of a lower plate UP-a to an upper surface of the lower plate UP-a. Accordingly, after the first and second etching operations, the preliminary lower plate UP2-P may be changed to the lower plate UP-a in which the pattern HO-a is formed between a first lower plate UP2a and a second lower plate UP2b.

The lower plate UP-a formed through the method for manufacturing a display device DD according to an embodiment may include the first lower plate UP2a overlapping a first non-folding region NFA1 and the second lower plate UP2b overlapping a second non-folding region NFA2. The first lower plate UP2a and the second lower plate UP2b may be spaced part from each other by the folding region FA.

Referring to FIGS. 10D and 10E, the pattern HO-a may be formed through the etching operation in a state in which the acid-resistant layer ARL (see FIG. 10C) is formed, and then the acid-resistant layer ARL may be removed. The operations of forming and removing the acid-resistant layer ARL on the display panel DP may be substantially the same as the processes described with reference to FIGS. 8C and 8D.

A sensor layer IS and an optical layer RCL may be sequentially formed on the display panel DP on which the acid-resistant layer ARL is removed, and a window module WM including a coating layer CL according to an embodiment may be formed on the optical layer RCL. A window adhesive layer AP-W may be formed by supplying an optically clear adhesive film or an optically clear adhesive resin layer on the display module DM. The process of forming the window module WM described with reference to FIG. 10E may be substantially the same as the process of forming the window module WM described with reference to FIGS. 8D and 8E.

Hereinafter, referring to Examples and Comparative Examples, a result of evaluation of characteristics of a display device DD including a coating layer CL according to an embodiment of the invention will be described. In addition, Examples shown below are examples for helping understand the invention, and a range of the invention is not limited thereto.

### 1. Evaluation of Characteristics of Display Device 1

Folding characteristics and impact resistances of display devices were evaluated and shown in Table 1. The display devices according to Examples and Comparative Examples were manufactured so as to all identically have a structure of FIG. 3, except that coating layers thereof have different elastic moduli. Thicknesses of the coating layers in the display devices according to Examples and Comparative Examples were all about 100 μm.

In Table 1 below, “module” means a display module. In addition, in Table 1 below, “UT” means a thin-film glass, “TFE” means an encapsulation layer of a display panel DP, and “UP” means a lower plate. In addition, in Table 1 below, “x” means that the display device DD was not folded, and a buckling defect occurred in the coating layer CL.

TABLE 1

| Classification | | | | | |
|---|---|---|---|---|---|
| | Elastic | Torque | | | |
| | modulus of | (N · mm) | Strain (%) | | |
| | coating layer | Module | UT | TFE | UP |
| Comparative | 100 MPa | x | | | |
| Example 1 | | | | | |
| Comparative | 200 MPa | x | | | |
| Example 2 | | | | | |
| Comparative | 300 MPa | x | | | |
| Example 3 | | | | | |
| Comparative | 400 MPa | x | | | |
| Example 4 | | | | | |
| Example 1 | 500 MPa | 129.1 | 1.04 | 0.15 | 0.67 |
| Example 2 | 600 MPa | 127.04 | 1.04 | 0.15 | 0.67 |
| Example 3 | 700 MPa | 136.55 | 1.04 | 0.15 | 0.68 |
| Example 4 | 800 MPa | 136.42 | 1.11 | 0.15 | 0.68 |
| Example 5 | 900 MPa | 138.96 | 1.1 | 0.15 | 0.68 |
| Example 6 | 1000 MPa | 146.98 | 1.15 | 0.15 | 0.68 |
| Comparative | 2000 MPa | 167.77 | 1.29 | 0.15 | 0.69 |
| Example 5 | | | | | |
| Comparative | 3000 MPa | 196.76 | 1.49 | 0.15 | 0.7 |
| Example 6 | | | | | |
| Comparative | 4000 MPa | 229.13 | 1.59 | 0.16 | 0.7 |
| Example 7 | | | | | |
| Comparative | 5000 MPa | 257.23 | 1.75 | 0.16 | 0.71 |
| Example 8 | | | | | |
| Comparative | 6000 MPa | 282.17 | 1.86 | 0.16 | 0.71 |
| Example 9 | | | | | |
| Comparative | 7000 MPa | 307.32 | 1.97 | 0.16 | 0.72 |
| Example 10 | | | | | |

Referring to Table 1, the display devices according to Examples 1 to 6 include the coating layer CL and the lower plate UP according to an embodiment so that torques of the display modules are equal to or less than about 150 N·mm, and strains of the thin-film glass are equal to or less than about 1.3%. It may be seen that the display devices according to Examples 1 to 6 include a structure in which a support member (for example, the lower plate UP) disposed under the display module DM has a reduced stack thickness, and the coating layer CL is directly disposed on the thin-film glass UT without an intervening adhesive layer, thereby showing a repulsive force not deteriorating folding characteristics and an excellent impact resistance.

Meanwhile, the display devices according to Comparative Examples 1 to 4 include coating layers of which the elastic moduli are less than about 500 MPa together with thicknesses of about 100 μm. The elastic moduli of the coating layers of the display devices according to Comparative Examples 1 to 4 are much lower than those according to Examples so that buckling occurs due to compressive stresses applied on the coating layers, thereby showing results that the display devices are not folded.

In addition, the display devices according to Comparative Examples 5 to 10 include coating layers having elastic moduli of at least about 2000 MPa together with thicknesses of about 100 μm. It may be seen that the elastic moduli of the coating layers of the display devices according to Comparative Examples 5 to 10 are much higher than those according to Examples so that folding characteristics are deteriorated due to increase in repulsive forces, and the strains of the thin-film glasses exceed about 1.3% to increase possibility that a crack occurs on the thin-film glass of each thereof.

### 2. Evaluation of Characteristics of Display Devices 2

Folding characteristics and impact resistances of display devices according to thicknesses of the coating layers thereof were evaluated and shown in Table 2. The display devices according to Examples and Comparative Examples were manufactured so as to all identically have a structure of FIG. 3, except that the coating layers thereof have different elastic moduli. In the display devices according to Examples and Comparative Examples, the elastic moduli of the coating layers were all the same as about 2000 MPa, and the thicknesses of the coating layers were shown in Table 2.

In Table 2 below, “module” means a display module. In addition, in Table 2 below, “UT” means a thin-film glass, “TFE” means an encapsulation layer of a display panel, and “UP” means a lower plate.

TABLE 2

| | Thickness | Torque (N · mm) | Strain (%) | | |
|---|---|---|---|---|---|
| | Layer | | | | |
| Item | UT | Module | UT | TFE | UP |
| Comparative | 100 μm | 167.77 | 1.29 | 0.15 | 0.69 |
| Example 11 | | | | | |
| Comparative | 90 μm | 153.45 | 1.31 | 0.15 | 0.69 |
| Example 12 | | | | | |
| Example 7 | 80 μm | 146.86 | 1.27 | 0.15 | 0.69 |
| Example 8 | 70 μm | 134.4 | 1.19 | 0.14 | 0.7 |
| Example 9 | 65 μm | 128.48 | 1.17 | 0.14 | 0.7 |
| Example 10 | 60 μm | 123.91 | 1.11 | 0.15 | 0.67 |
| Example 11 | 50 μm | 119.61 | 1.27 | 0.14 | 0.69 |

Referring to Table 2, display devices according to Examples 7 to 11 include coating layers and lower plates according to an embodiment so that torques of the display modules are equal to or less than about 150 N·mm, and the strains of the thin-film glasses are equal to or less than about 1.3%. Accordingly, it may be confirmed that the display devices according to Examples show excellent folding characteristics and a good impact resistance.

In addition, Example 7 including a coating layer having an elastic modulus of about 2000 MPa together with a thickness of about 80 μm shows an equally excellent effect as Example 1 including an elastic modulus of 1000 MPa together with a thickness of about 100 μm. Accordingly, it may be seen that in order to perform stable folding characteristics, when an elastic modulus, of the coating layer, of about 1000 MPa is increased, a thickness, of a coating layer, of about 20 μm should be reduced.

Meanwhile, the display devices according to Comparative Examples 11 and 12 include coating layers having elastic moduli of about 2000 MPa together with thicknesses of at least about 90 μm to show torques exceeding about 150 N·mm. That is, it may be seen that the display devices according to Comparative Examples 11 and 12 show deteriorated folding characteristics due to increase in repulsive forces thereof.

### 3. Evaluation of Characteristics of Display Devices 3

Folding characteristics and impact resistances of display devices according to Examples were evaluated and shown in Table 3. The display devices according to Examples were manufactured so as to all identically have a structure of FIG. 3, except that coating layers thereof have different thicknesses. In the display devices according to Examples, elastic moduli of the coating layers were all the same as about 1000 MPa, and thicknesses of the coating layers were shown in Table 3.

In Table 3 below, “module” means a display module. In addition, in Table 3 below, “UT” means a thin-film glass, “TFE” means an encapsulation layer of the display panel, and “UP” means a lower plate. In addition, each strain was evaluated by falling a steel pen at a height of about 3 centimeters (cm) from a subject to be measured.

TABLE 3

| | | Strain (%) | | |
|---|---|---|---|---|
| | | Layer | | |
| Item | | UT | TFE | UP |
| Example 1 | 100 μm | 2.88 | 0.1 | 0.11 |
| Example 2 | 90 μm | 2.99 | 0.1 | 0.1 |
| Example 3 | 80 μm | 3.29 | 0.11 | 0.11 |
| Example 4 | 70 μm | 3.5 | 0.12 | 0.12 |

Referring to Table 3, it may be confirmed that compared to Examples 1 to 3, Example 4 has a thin-film glass having a strain more than about 3.3% to have a relatively greater strain than other Examples. Accordingly, it may be seen that when the elastic modulus of the coating layer is about 1000 MPa together with a thickness of about 80 μm to about 100 μm, the display device shows an excellent impact resistance. In addition, it may be seen that when the elastic modulus of the coating layer is about 1000 MPa, together with having thicknesses of about 90 μm to about 100 μm as in Examples 1 and 2 show lower strains than Example 3 having a thickness of about 80 μm, thereby showing a more improved impact resistance.

FIG. 11 is a block diagram illustrating an electronic device 1000 according to an embodiment.

Referring to FIG. 11, in an embodiment, an electronic device 1000 may include a processor 1010, a memory device 1020, a storage device 1030, an input/output (“I/O”) device 1040, a power supply 1050, and a display apparatus 1060. Here, the display apparatus 1060 may correspond to the display device DD of FIG. 2. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display apparatus 1060. The display apparatus 1060 may be coupled to other components via the buses or other communication links. In an embodiment, the display apparatus 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a home appliance, a tablet PC, a vehicle display, a computer monitor, a notebook computer, an entertainment device like a head-mounted display apparatus, etc. In addition, the electronic device 1000 may be a television, a monitor, a notebook computer, or a tablet. In addition, the electronic device 1000 may be a car.

The display apparatus 1060 according to the embodiments may be applied to a device included in a computer, a notebook, a mobile phone, a smartphone, a smart pad, a PMP, a PDA, an MP3 player, or the like.

According to what is described above, a display device DD according to an embodiment may include a window module WM in which a coating layer having a specific modulus is directly disposed on a thin-film glass UT to show excellent folding characteristics and reliability such as impact resistance.

In addition, a display device DD according to an embodiment may have a lower plate UP directly disposed under the display panel DP to omit a protective film, a cover film, a metal plate, etc., between the display panel DP and the lower plate UP.

In addition, according to a method for manufacturing (or providing) a display device DD according to an embodiment, a coating layer CL which protects a thin-film glass UT within a window module WM may be directly formed on the thin-film glass UT without an intervening adhesive layer or a bonding layer. In addition, a lower member which protects a display panel DP may be formed by utilizing a preliminary lower substrate, without removing the preliminary lower substrate as compared to the removing of a carrier substrate which transfers or supports a base layer of the display panel DP. Accordingly, processes may be simplified by using the method for manufacturing a display device DD according to an embodiment, thereby reducing a manufacturing cost and a weight of the display device DD.

In the above, description has been made with reference to embodiments of the invention, but those skilled in the art or those of ordinary skill in the relevant technical field may understand that various modifications and changes may be made to the invention within the scope not departing from the spirit and the technology scope of the invention described in the claims to be described later. Therefore, the technical scope of the invention is not limited to the contents described in the detailed description of the specification, but should be determined by the claims.

What is claimed is:

1. An electronic device comprising:
a display module including:
a display panel;
a folding region at which the display module is foldable, and
a non-folding region adjacent to the folding region along a first direction;
a window module on the display module, the window module including:
a thin-film glass, and
a coating layer which is further from the display module than the thin-film glass, the coating layer having a thickness of about 50 micrometers to about 110 micrometers together with an elastic modulus of about 500 megapascals to about 3000 megapascals,
wherein the coating layer having a first elastic modulus equal to or more than about 500 megapascals and less than about 2000 megapascals includes the first elastic modulus together with the thickness being about 80 micrometers to about 100 micrometers; and
a glass substrate which faces the window module with the display module therebetween and in which a hole is defined overlapping the folding region.

2. The electronic device of claim 1, wherein the coating layer having a second elastic modulus of about 500 megapascals to about 1000 megapascals includes the second elastic modulus together with the thickness being about 90 micrometers to about 110 micrometers.

3. The electronic device of claim 1, wherein the coating layer having a third elastic modulus of about 1000 megapascals to about 2000 megapascals includes the third elastic modulus together with the thickness being about 70 micrometers to about 90 micrometers.

4. The electronic device of claim 1, wherein the thickness of the coating layer is about 80 micrometers to about 100 micrometers.

5. The electronic device of claim 1, wherein within the window module, the coating layer is directly on the thin-film glass.

6. The electronic device of claim 1, wherein the window module further includes a hard coating layer which is further from the display module than the coating layer.

7. The electronic device of claim 1, wherein a stacked structure having the glass substrate which faces the window module with the display module therebetween together with the coating layer which is further from the display module than the thin-film glass, provides a torque of the display module which is folded, the torque being equal to or less than about 150 N·mm.

8. The electronic device of claim 1, wherein a thickness of the glass substrate is smaller than the thickness of the coating layer.

9. The electronic device of claim 1, wherein the hole penetrates a thickness of the glass substrate.

10. The electronic device of claim 1, wherein the glass substrate comprises:
a base substrate which comprises glass and in which the hole is defined; and
at least one of a functional layer on an upper surface of the base substrate which is closest to the display panel and a protective layer on a lower surface of the base substrate which is furthest from the display panel.

11. The electronic device of claim 1, wherein an upper surface of the glass substrate which is closest to the display panel is in direct contact with a lower surface of the display panel which is closest to the glass substrate.

12. The electronic device of claim 1, further comprising an adhesive layer which is between the glass substrate and the display module and couples the glass substrate to the display module.

13. The electronic device of claim 1, wherein
the hole is provided in plural including a plurality of holes,
each of the plurality of holes has a major dimension which extends along a second direction crossing the first direction,
the plurality of holes comprise a first hole and a second hole spaced apart from each other in the first direction, and
the first hole and the second hole are misaligned along the first direction.

14. A method for providing an electronic device, the method comprising:
providing a glass substrate in which a hole is defined;
providing a display module on the glass substrate, the display module including a display panel, a folding region at which the display module is foldable and a non-folding region which is adjacent to the folding region along a first direction; and
providing a window module on the display module, including:
providing a thin-film glass, and
supplying a coating material on the thin-film glass to provide a coating layer which is further from the display module than the thin-film glass, the coating layer having a thickness of about 50 micrometers to about 110 micrometers together with an elastic modulus of about 500 megapascals to about 3000 megapascals,
wherein the coating layer having a first elastic modulus equal to or more than about 500 megapascals and less than about 2000 megapascals includes the first elastic modulus together with the thickness being about 80 micrometers to about 100 micrometers.

15. The method of claim 14, wherein the providing of the glass substrate comprises etching portions of the glass substrate which correspond to the folding region, to provide the hole in plural in the glass substrate, while the display module is on the glass substrate.

16. The method of claim 14, wherein the providing of the glass substrate comprises etching a portion of the glass substrate which corresponds to the folding region, to provide the hole in the glass substrate, while the display module is on the glass substrate.

17. The method of claim 16, further comprising:
providing the glass substrate having a preliminary thickness;
providing the display module on the glass substrate having the preliminary thickness, and
reducing the preliminary thickness of the glass substrate by supplying an etching solution to the glass substrate while the display module is on the glass substrate having the preliminary thickness.

18. The method of claim 17, wherein the providing of the glass substrate further comprises irradiating a laser to the glass substrate which has the preliminary thickness to provide a preliminary hole in the glass substrate, before the reducing of the preliminary thickness of the glass substrate.

19. The method of claim 17, wherein the providing of the glass substrate further comprises providing an etching stopper layer on the display module which is on the glass substrate having the preliminary thickness.

20. The method of claim 14, wherein a thickness of the glass substrate is smaller than the thickness of the coating layer.
